(19) United States
(12) Patent Application Publication
(10) Pub. No.: US 2025/0040167 A1
(43) Pub. Date: Jan. 30, 2025

(54) GATE-ALL-AROUND FIELD EFFECT TRANSISTORS

(71) Applicant: GlobalFoundries U.S. Inc., Malta, NY (US)

(72) Inventors: Navneet K. JAIN, Milpitas, CA (US); Romain H. A. FEUILLETTE, Williston, VT (US); David C. PRITCHARD, Glenville, NY (US); James P. MAZZA, Saratoga Springs, NY (US); Hong YU, Clifton Park, NY (US)

(21) Appl. No.: 18/225,907

(22) Filed: Jul. 25, 2023

(51) Int. Cl. H01L 29/775; H01L 27/092; H01L 29/06; H01L 29/423; H01L 29/66

(52) U.S. Cl. CPC H01L 29/775; H01L 27/0922; H01L 29/0673; H01L 29/42392; H01L 29/66439; H01L 29/66553

(57) ABSTRACT

The present disclosure relates to semiconductor structures and, more particularly, to gate-all-around field effect transistors and methods of manufacture. The structure includes: a plurality of stacked semiconductor nanosheets over a semiconductor substrate; a plurality of gate structures surrounding the plurality of semiconductor nanosheets; a conductive material between the plurality of semiconductor nanosheets and the plurality of gate structures; an inner sidewall spacer adjacent to each of the plurality of gate structures and conductive material; and source/drain regions on opposing sides of the plurality of gate structures, separated therefrom by the inner sidewall spacer.

### BACKGROUND

The present disclosure relates to semiconductor structures and, more particularly, to gate-all-around field effect transistors and methods of manufacture.

Gate-All-Around (GAA) nanosheet field effect transistors (FETs) include stacks of nanosheets or nanowires with spacers that are surrounding the perimeter of multiple nanosheet channel regions with a metal gate stack. Nanosheet transistors have increased performance over planar transistors by providing increased device density and performance. However, nanosheet FETs are isolated from a substrate bias in fully depleted semiconductor on insulator (FDSOI) technologies, which may limit their ability to modulate Vt of the FDSOI device.

### SUMMARY

In an aspect of the disclosure, a structure comprises: a plurality of stacked semiconductor nanosheets over a semiconductor substrate; a plurality of gate structures surrounding the plurality of semiconductor nanosheets; a conductive material between the plurality of semiconductor nanosheets and the plurality of gate structures; an inner sidewall spacer adjacent to each of the plurality of gate structures and conductive material; and source/drain regions on opposing sides of the plurality of gate structures, separated therefrom by the inner sidewall spacer.

In an aspect of the disclosure, a structure comprises: a plurality of stacked semiconductor nanosheets; a plurality of gate structures surrounding a pair of the plurality of stacked semiconductor nanosheets; and a back gate bias material between the pair of the plurality of stacked semiconductor nanosheets.

In an aspect of the disclosure, a method comprises: forming a plurality of stacked semiconductor nanosheets over a semiconductor substrate; forming a plurality of gate structures surrounding the plurality of semiconductor nanosheets; forming a conductive material between the plurality of semiconductor nanosheets and the plurality of gate structures; forming an inner sidewall spacer adjacent to each of the plurality of gate structures and conductive material; and forming source/drain regions on opposing sides of the plurality of gate structures, separated therefrom by the inner sidewall spacer.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A shows a top view of a gate-all-around field effect transistor and respective fabrication processes in accordance with aspects of the present disclosure.

FIG. 1B shows a cross-sectional view of the structure of FIG. 1A along line A-A.

FIG. 1C shows a cross-sectional view of the structure of FIG. 1A along line B-B.

FIG. 2 shows a cross-sectional view of a gate-all-around field effect transistor in accordance with additional aspects of the present disclosure.

FIGS. 3A-3F show cross-sectional views of respective fabrication processes of a gate-all-around field effect transistor in accordance with aspects of the present disclosure.

### DETAILED DESCRIPTION

The present disclosure relates to semiconductor structures and, more particularly, to gate-all-around field effect transistors and methods of manufacture. In embodiments, the gate-all-around field effect transistors are vertical transistors wrapped around stacked nanosheets which alternate with different material. The nanosheets may be a semiconductor-on-insulator (SOI) material which acts as a channel region for each gate of the gate-all-around field effect transistors (FETs). The different material, on the other hand, may be buried oxide and bulk semiconductor material. Advantageously, the present disclosure provides improved back gate biasing capability due to a reduced or lack of strain in the vertical FETs. Moreover, the present disclosure provides the ability to adjust Vt from the back gate bias.

In more specific embodiments, the gate-all-around field effect transistors comprise stacked nanosheets of semiconductor material, e.g., Si, with a gate structure associated with each nanosheet. In embodiments, for example, the stacked structure includes a plurality semiconductor nanosheets with different material between the nanosheets and the gate structures wrapping around a pair of the nanosheets. The nanosheets may be SOI material which acts as a channel region for the gate structures. In embodiments, for example, the gate structures come into contact with the nanosheets of semiconductor material on all sides, which makes continuous scaling possible. The gate structures may be n-FET and/or p-FET devices. The different material may be bulk semiconductor material and buried insulator material may also be provided in between adjacent nanosheets.

The transistors of the present disclosure can be manufactured in a number of ways using a number of different tools. In general, though, the methodologies and tools are used to form structures with dimensions in the micrometer and nanometer scale. The methodologies, i.e., technologies, employed to manufacture the transistors of the present disclosure have been adopted from integrated circuit (IC) technology. For example, the structures are built on wafers and are realized in films of material patterned by photolithographic processes on the top of a wafer. In particular, the fabrication of the transistors uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

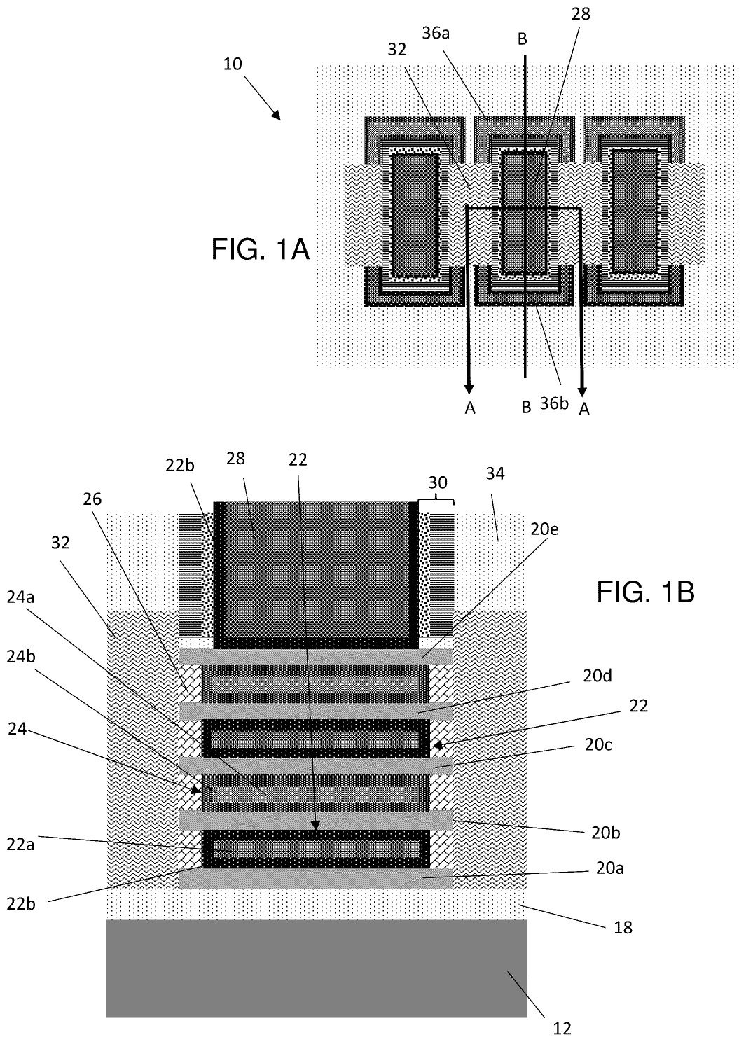

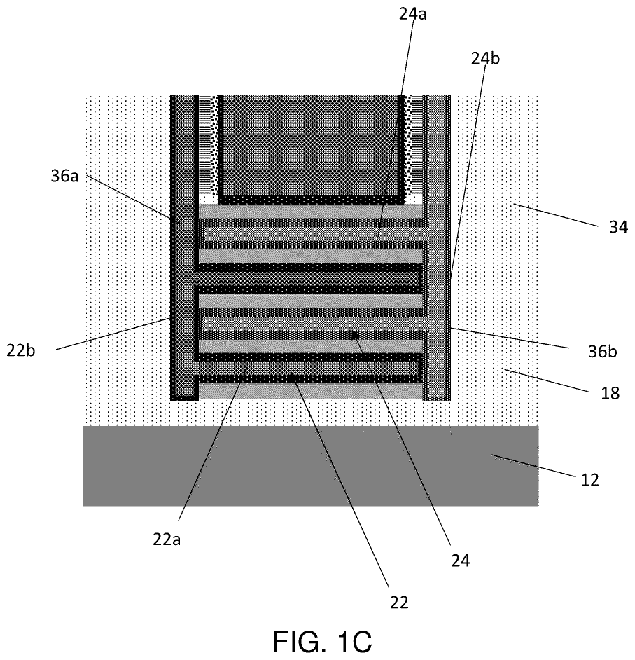

FIG. 1A shows a top view of a gate-all-around field effect transistor and respective fabrication processes in accordance with aspects of the present disclosure. FIG. 1B shows a cross-sectional view of the structure of FIG. 1A along line A-A; whereas FIG. 1C shows a cross-sectional view of the structure of FIG. 1A along line B-B. In particular, FIGS. 1A-1C show a structure 10, e.g., gate-all-around field effect transistor, with nanosheets 20a-20e composed of semiconductor material, alternating with gate structures 22 and conductive material 24a isolated from the nanosheets 20a-20e by an insulator material 24b. A voltage can be applied to the conductive material 24a to provide a back gate bias to the gate structures 22.

More specifically, and referring to FIGS. 1A and 1B, the structure 10 includes a bulk semiconductor substrate 12. The bulk semiconductor substrate 12 may be a handle substrate used in SOI technologies. The bulk semiconductor substrate 12 may be fully depleted and composed of any suitable semiconductor material including, but not limited to, Si, SiGe, SiGeC, SiC, GaAs, InAs, InP, and other III/V or II/VI compound semiconductors. In embodiments, the bulk semiconductor substrate 12 may preferably be a p-type semiconductor substrate with any suitable single crystallographic orientation (e.g., a (100), (110), (111), or (001) crystallographic orientation).

Referring to FIGS. 1B and 1C, an insulator material 18 may be formed over the bulk semiconductor substrate 12. In embodiments, the insulator material 18 may be used to isolate the bulk semiconductor substrate 12 from the remaining structures of the device. The insulator material 18 may include any suitable dielectric material such as silicon dioxide, silicon nitride, silicon oxynitride, boron nitride or a combination thereof. In one embodiment, the insulator material 18 may be a buried oxide layer (BOX) formed by a deposition process, such as chemical vapor deposition (CVD), plasma enhanced chemical vapor deposition CVD (PECVD) or physical vapor deposition (PVD). In another embodiment, the buried material 18 may be formed using a thermal growth process, such as thermal oxidation, to convert a surface portion of the bulk semiconductor substrate 12.

FIGS. 1B and 1C also show nanosheets 20a, 20b, 20c, 20d, 20e alternating with the gate structures 22 and different material represented by reference numeral 24. More specifically, each of the gate structures 22 surrounds a pair of nanosheets 20a, 20b, 20c, 20d, 20e and a different material 24. By way of example, a gate structure 22 surrounds a pair of nanosheets 20b, 20c and different material 24, where the different material 24 is between the nanosheets 20b, 20c. Similarly, another gate structure 22 surrounds a pair of nanosheets 20c, 20d and different material 24 between the nanosheets 20c, 20d.

In embodiments, the nanosheets 20a, 20b, 20c, 20d, 20e may be composed of semiconductor material. For example, the nanosheets 20a, 20b, 20c, 20d, 20e may be semiconductor-on-insulator material. In one embodiments, the nanosheets may be silicon-on-insulator material.

The gate structures 22 may be composed of a gate body 22a, e.g., metal or polysilicon, surrounded by a gate dielectric material 22b. The gate body 22a may be any appropriate gate workfunction metal including, for example, Ti, TiAIC, Al, TiAl, TaN, TiN, TIC, Co, TiC, TaC, HfTi, TiSi, or TaSi. The workfunction material may be formed by CVD, physical vapor deposition (PVD), including sputtering, atomic layer deposition (ALD) or other suitable method as is known in the art. In embodiments, the gate dielectric material 22b may be a high-k gate dielectric material, e.g., HfO₂ Al₂O₃, Ta₂O₃, TiO₂, La₂O₃, SrTiO₃, LaALO₃, ZrO₂, Y₂O₃, Gd₂O₃, and combinations including multilayers thereof. The gate dielectric material 22b may be deposited by an ALD process or other suitable method as is known in the art.

The different materials 24 may include a conductive material 24a surrounded by an insulator material 24b. In embodiments, the conductive material 24a may be Si or polysilicon material; whereas the insulator material 24b may be an oxide material (e.g., SiO₂). It should be understood by those of skill in the art that other conductive material and insulator material may be used for the materials 24a, 24b. For example, the material 24a may be a metal or metal alloy. In embodiments, the conductive material 24a may be used to provide a back gate bias to the gate structures 22.

As further shown in FIGS. 1B and 1C, sidewall spacers 26 surround the different material 24 (e.g., semiconductor material 24a and insulator material 24b) and respective gate structures 22. The sidewall spacers 26 are located between adjacent nanosheets 20a, 20b, 20c, 20d, 20e. In embodiments, the sidewalls spacers 26 may be used to isolate the different material 24 (e.g., semiconductor material 24a and insulator material 24b) and respective gate structures 22 from raised source/drain regions 32 as shown in FIGS. 1B and 1C. The sidewall spacers 26 may be SiN or other low-k dielectric materials such as SiOCN, SiBCN, etc.

The raised source/drain regions 32 may be epitaxial semiconductor material, selectively grown from the bulk semiconductor substrate 12 and the stacked nanosheets 20a, 20b, 20c, 20d, 20e. In embodiments, the epitaxial semiconductor material may be silicon germanium (SiGe) or SiP, as examples. The raised source/drain regions 32 may be in-situ doped with an appropriate dopant for an NFET device or PFET device as is understood by those of skill in the art such that no further explanation is required for a complete understanding of the present disclosure. Alternatively, the raised source/drain regions 32 may be subjected to an ion implantation process as is known in the art.

FIGS. 1A and 1B further show an upper gate body 28 and sidewall spacers 30. The upper gate body 28 may be provided over the uppermost gate structure 22, with the sidewall spacers 30 surrounding the upper gate body 28. In embodiments, the upper gate body 28 may be the same material as the gate structures 22, with a gate dielectric material 22b contacting the uppermost nanosheet 20e. The sidewall spacers 30 may be nitride material and oxide materials, as examples. An interlevel dielectric material 34 may be deposited on the structure.

FIG. 1C further shows contacts 36a, 36b within the interlevel dielectric material 34. The contacts 36a may electrically connect to the semiconductor material 24a from a side of the structure (as the material 24 is provided in a tiered or offset configuration). This will allow a voltage bias to be applied to the backside of the gate structures 22. In this way, it is possible to provide a back gate bias.

In embodiments, the contacts 36a can be etched deeper to make a side contact to the semiconductor material 24a to increase contact area, if necessary. The contacts 36b may electrically connect to the gate structures 22 from another side of the structure (different from the contacts 36a). The contacts 36a will be lined with the gate dielectric material 22b; whereas the contacts 36b will be lined with the insulator material 24b. In this way, the contacts 36a, 36b will be isolated from the semiconductor material 24a and the gate structures 22, respectively. The contacts 36a, 36b will also be isolated from the nanosheets 20a-20e. Although not shown, it should be understood that contacts are also formed to the source/drain regions 28.

The contacts 36a, 36b may be formed by conventional lithography, etching and deposition processes as is known in the art. By way of example, the interlevel dielectric material 34 may be deposited over the structure, e.g., source/drain regions 28, etc. by a conventional CVD process. The interlevel dielectric material 34 may be oxide, nitride and/or a combination of oxide and nitride. A resist formed over the interlevel dielectric material 34 is exposed to energy (light) and developed utilizing a conventional resist developer to form a pattern (openings). An etching process with a selective chemistry, e.g., reactive ion etching (RIE), will be used to transfer the pattern from the patterned photoresist layer to the interlevel dielectric material 34 to form one or more trenches in the interlevel dielectric material 34 through the openings of the resist. Following the resist removal by a conventional oxygen ashing process or other known stripants, conductive material can be deposited by any conventional deposition processes, e.g., CVD processes. Any residual material on the surface of the interlevel dielectric material 34 can be removed by conventional chemical mechanical polishing (CMP) processes. In embodiments, the conductive material may be tungsten or aluminum with a liner material, e.g., TaN or TiN.

Prior to forming the contacts 36a, 36b, a silicide process may be used to provide silicide contacts on the source/drain regions 28 and any exposed semiconductor material, e.g., semiconductor material 24a. As should be understood by those of skill in the art, the silicide process begins with deposition of a thin transition metal layer, e.g., nickel, cobalt or titanium, over fully formed and patterned semiconductor devices (e.g., source/drain regions 28 and respective semiconductor material 24a). After deposition of the material, the structure is heated allowing the transition metal to react with exposed silicon (or other semiconductor material as described herein) forming a low-resistance transition metal silicide. Following the reaction, any remaining transition metal is removed by chemical etching, leaving silicide contacts. It should be understood by those of skill in the art that silicide contacts will not be required on the gate structures 22 composed of a metal material.

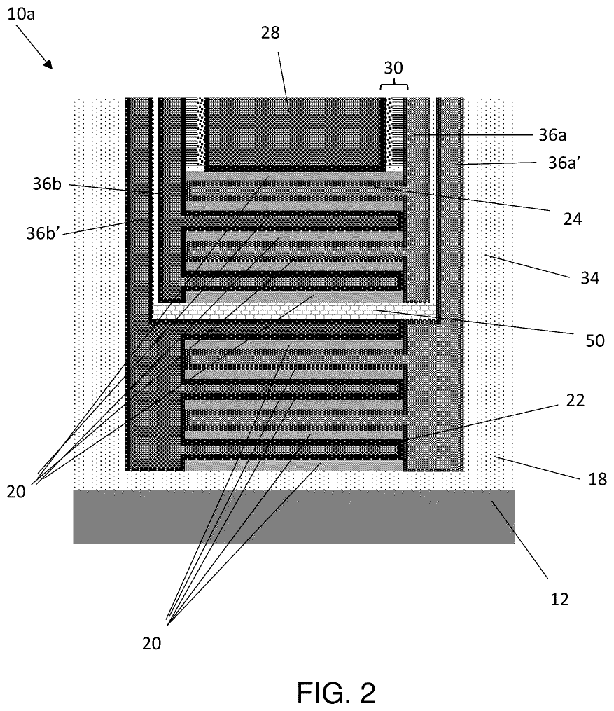

FIG. 2 shows another structure in accordance with aspects of the present disclosure. In embodiments, the structure 10a comprises a complementary FET. The complementary FET comprises an NFET 100 and a PFET 200. In embodiments, the FETs 100, 200 are separated by an insulator material 50, e.g., SiO₂, and each comprise the features described with respect to FIGS. 1A-1C. For example, both FETs 100, 200 include nanosheets 20 alternating with gate structures 22 and the different material 24. In this embodiment, contacts 36a, 36a′, 36b, 36b′ are provided to each of the gate structures 22 and the different material 24 of the different FETs 100, 200, respectively, in a manner similar to that which is described with respect to FIG. 1C.

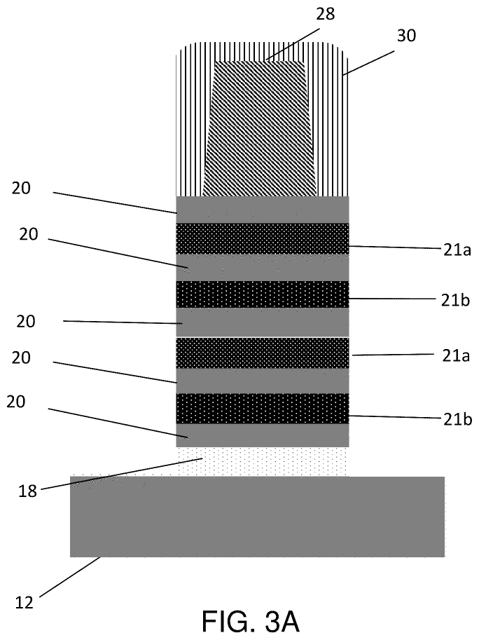

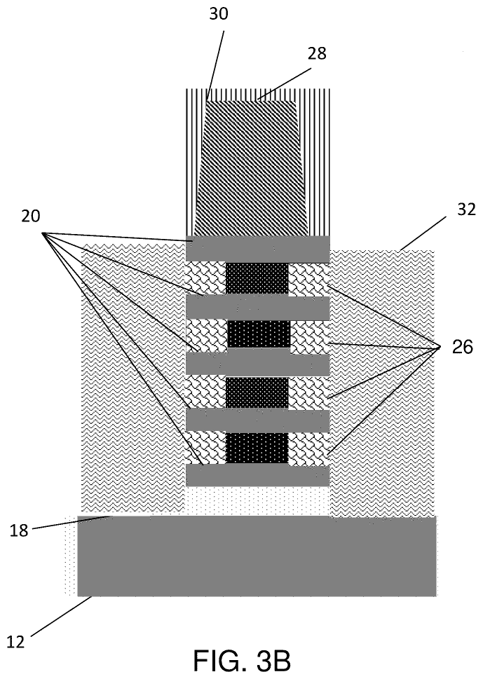

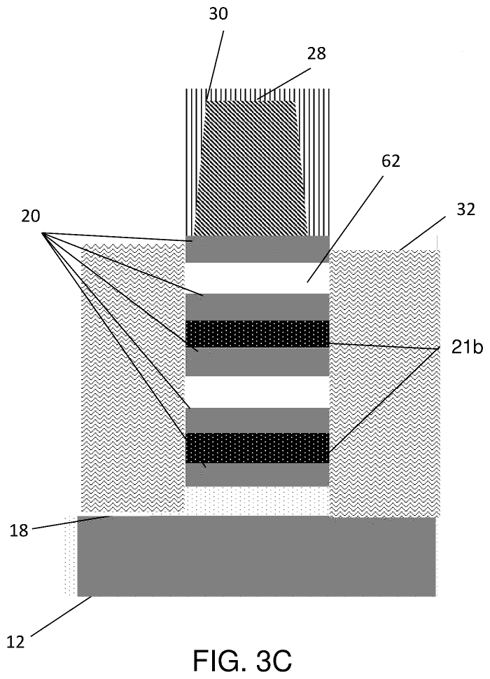

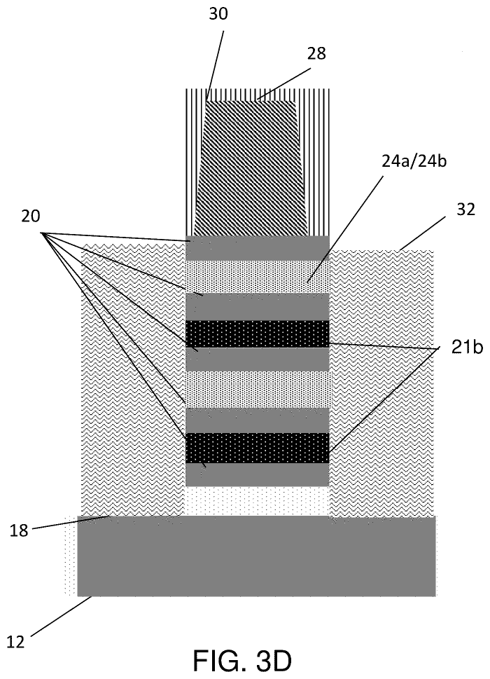

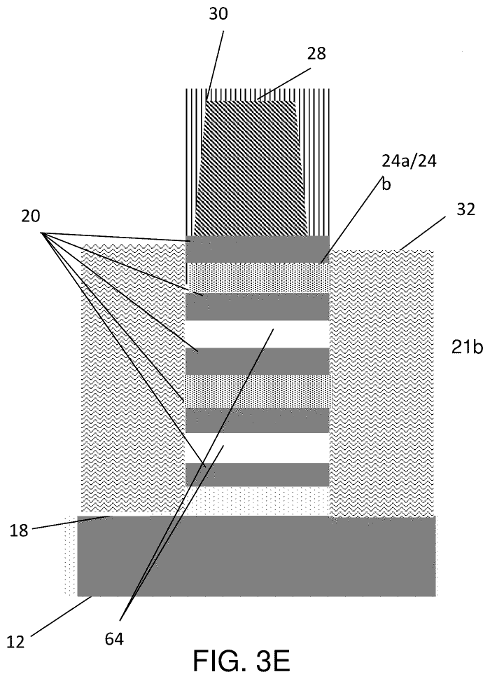

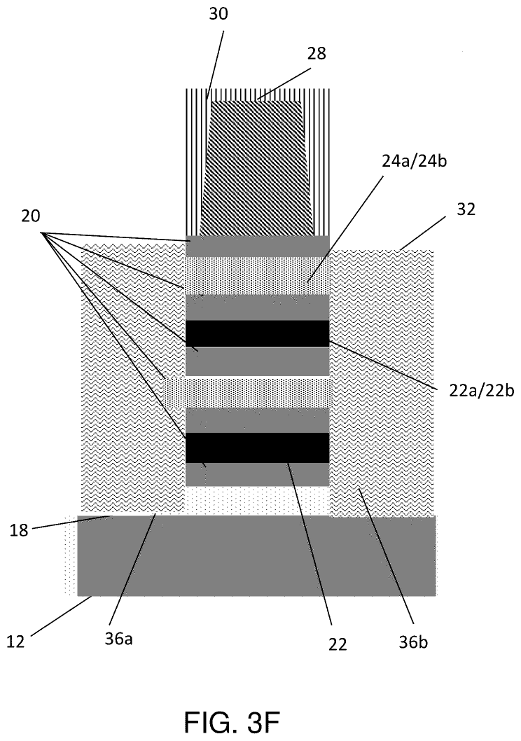

FIGS. 3A-3F show cross-sectional views of respective fabrication processes of a gate-all-around field effect transistor in accordance with aspects of the present disclosure. It should be understood by those of ordinary skill in the art that FIGS. 3A-3F show a cross-sectional view from a single perspective view of the respective fabrication processes described herein; however, with these respective views, one of ordinary skill in the art would understand the necessary steps required for the fabrication processes described herein.

FIG. 3A shows a beginning structure which includes the semiconductor substrate 10, insulator material 18 and a plurality of nanosheets 20 alternating with materials 21a, 21b. In embodiments, the materials 21a, 21b have different material compositions than the nanosheets 20 to provide an etch selectivity for subsequent fabrication processes. In addition, material 21a and material 21b may have different material compositions to also provide etch selectivity for subsequent fabrication processes. By way of non-limiting illustrative example, the materials 21a, 21b may be semiconductor material and, preferably, SiGe material with different Ge concentrations. For example, material 21a may be SiGex and material 21b may be SiGey 21b, where “x” and “y” represent different Ge concentrations. As should be understood by those of skill in the art, the materials 21a, 21b may be stacked in a tiered (or offset) configuration, similar to that shown in FIG. 1C. This will allow subsequent formation of contacts to the different structures.

In this implementation, the nanosheets 20 may be Si material and, preferably, epitaxially grown Si material. In embodiments, each of the nanosheets 20 and materials 21a, 21b may be epitaxially grown. It should be understood, though, that other material compositions and deposition processes are contemplated herein, where the materials would have different material compositions with different etch selectivity.

Still referring to FIG. 3A, the upper gate body 28 and sidewall spacer 30 may be provided on the uppermost nanosheet 20; although alternative embodiments may contemplate the upper gate body 28 and sidewall spacer 30 be provided on either of the materials 21a, 21b. The upper gate body 28 may be deposited by a CVD process, followed by a conventional patterning process, e.g., lithography and etching process as is known in the art. The sidewall spacer 30 may be deposited on the patterned upper gate body 28 and patterned using a conventional anisotropic etching process as is known in the art. In embodiments, sidewall spacer material 28 may remain on an upper surface of the cap material 30. The upper gate body 28 and sidewall spacer 30 may be used as a hardmask to pattern the alternating nanosheets 20 and different materials 21a, 21b. The patterning process may also be used to remove portions of the insulator material 18 in order to expose the underlying semiconductor substrate 12. This will form an opening for subsequent source/drain formation.

In FIG. 3B, the sidewall spacers 26 may be formed by partially etching the materials 21a, 21b between the nanosheets 20, followed by a conventional deposition process. The raised source/drain regions 32 may be epitaxially grown on the semiconductor substrate 12, with the sidewall spacers 26 acting as isolation structures for subsequent gate structure formation.

In FIG. 3C, the material 21a is removed by a selective etch process to form cavities 62. This process can be a maskless process due to the etch selectivity of the material 21a. In this etching process, the material 21b and the nanosheets 20 will not be etched or attacked.

In FIG. 3D, the cavities are filled with the material 24a, 24b by conventional deposition processes. For example, silicon or polysilicon material may be formed by an epitaxial process, whereas insulator material may be formed by a conventional CVD process.

In FIG. 3E, the material 21b is removed by a selective etch process to form cavities 64. This process can be a maskless process due to the etch selectivity of the material 21b. In this etching process, the material 24a, 24b and the nanosheets 20 will not be etched or attacked.

In FIG. 3F, the cavities are filled with the gate material 22a, 22b by conventional deposition processes. For example, gate dielectric material 22b may be deposited by a physical vapor deposition (PVD) including sputtering, atomic layer deposition (ALD) or other suitable method. The gate dielectric material 22b can be a high-k gate dielectric material, e.g., HfO₂ Al₂O₃, Ta₂O₃, TiO₂, La₂O₃, SrTiO₃, LaALO₃, ZrO₂, Y₂O₃, Gd₂O₃, and combinations including multilayers thereof. The gate body 22a may be polysilicon material or a workfunction material known to those of skill in the art. The polysilicon material may be epitaxially grown; whereas a gate metal may be deposited by any conventional deposition method, e.g., CVD, PVD, etc. In this way, the gate material 22a, 22b will wraparound a pair of nanosheets and the different material 24.

As further shown in FIG. 1C, the contacts 36a, 36b may be formed to the gate structures 22 and different material 24. The wiring structures or interconnect structures (e.g., contacts 26a, 36b) can be formed by conventional lithography, etching and deposition methods known to those of skill in the art and as described above.

The transistors can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a plurality of stacked semiconductor nanosheets over a semiconductor substrate;
a plurality of gate structures surrounding the plurality of semiconductor nanosheets;
a conductive material between the plurality of semiconductor nanosheets and the plurality of gate structures;
an inner sidewall spacer adjacent to each of the plurality of gate structures and conductive material; and
source/drain regions on opposing sides of the plurality of gate structures, separated therefrom by the inner sidewall spacer.

2. The structure of claim 1, further comprising a first contact electrically connecting to the plurality of gate structures and a second contact electrically connecting to the conductive material.

3. The structure of claim 2, wherein the first contact electrically connects to the plurality of gate structures from a first side and the second contact electrically connects to the conductive material from a second side.

4. The structure of claim 3, wherein the plurality of gate structures and the conductive material are tiered.

5. The structure of claim 1, wherein the plurality of gate structures comprise a gate dielectric material and a gate body comprising polysilicon material.

6. The structure of claim 1, wherein the plurality of gate structures comprise a gate high-k dielectric material and a gate body comprising a workfunction metal.

7. The structure of claim 1, wherein the plurality of gate structures surround a pair of the plurality of semiconductor nanosheets.

8. The structure of claim 7, wherein the conductive material is surrounded by a dielectric material contacting the plurality of semiconductor nanosheets.

9. The structure of claim 1, wherein the plurality of stacked semiconductor nanosheets comprise silicon on insulator material.

10. The structure of claim 1, wherein the plurality of gate structures comprise wraparound gate structures.

11. The structure of claim 1, wherein the plurality of gate structures comprise one of an NFET and a PFET.

12. The structure of claim 1, wherein the plurality of gate structures comprise an NFET and a PFET, separated by an insulator material.

13. A structure comprising:
a plurality of stacked semiconductor nanosheets;
a plurality of gate structures surrounding a pair of the plurality of stacked semiconductor nanosheets; and
a back gate bias material between the pair of the plurality of stacked semiconductor nanosheets.

14. The structure of claim 13, wherein the plurality of stacked semiconductor nanosheets comprise Si material.

15. The structure of claim 13, wherein the plurality of gate structures comprise a gate dielectric material wrapping around the pair of the plurality of stacked semiconductor nanosheets and a conductive gate body.

16. The structure of claim 13, wherein the back gate bias material comprises a conductive material wrapped by an insulator material.

17. The structure of claim 13, wherein the plurality of gate structures comprise two gate structures.

18. The structure of claim 13, further comprising a semiconductor nanosheet below a bottommost gate structure of the plurality of gate structures.

19. The structure of claim 13, wherein:
the plurality of stacked semiconductor nanosheets comprise at least four nanosheets;
the plurality of gate structures comprise at least three gate structures each of which surround a pair of the plurality of stacked semiconductor nanosheets, with a common semiconductor nanosheet being shared with one of the gate structures of the at least three gate structures; and
the back gate bias material comprises two different layers between a respective pair of the plurality of stacked semiconductor nanosheets.

20. A method comprising:
forming a plurality of stacked semiconductor nanosheets over a semiconductor substrate;
forming a plurality of gate structures surrounding the plurality of semiconductor nanosheets;
forming a conductive material between the plurality of semiconductor nanosheets and the plurality of gate structures;
forming an inner sidewall spacer adjacent to each of the plurality of gate structures and conductive material; and
forming source/drain regions on opposing sides of the plurality of gate structures, separated therefrom by the inner sidewall spacer.
